(19) United States
(12) Patent Application Publication
(10) Pub. No.: US 2009/0065864 A1
(43) Pub. Date: Mar. 12, 2009

(54) Semiconductor Device and Method of Fabricating the Same

(76) Inventor: SANG YONG LEE, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/204,963

(22) Filed: Sep. 5, 2008

(30) Foreign Application Priority Data
Sep. 7, 2007 (KR) 10-2007-0090747

(51) Int. Cl. H01L 29/78; H01L 21/336

(52) U.S. Cl. 257/343; 438/280; 257/E29.261; 257/E21.424

(57) ABSTRACT

A semiconductor device and a method of fabricating the same are provided. The semiconductor device can include a buried conductive layer in a semiconductor substrate, an epitaxial layer on the buried conductive layer, and a plug passing through the epitaxial layer. The plug can be electrically connected to the buried conductive layer and can have an insulating layer around it, isolating the plug from an adjacent active area.

### CROSS-REFERENCE TO RELATED APPLICATION

The present application claims the benefit under 35 U.S.C. §119 of Korean Patent Application No. 10-2007-0090747, filed Sep. 7, 2007, which is hereby incorporated by reference in its entirety.

### BACKGROUND

Metal oxide semiconductor field effect transistors (MOSFETs) are often used as power devices. In general a MOSFET has higher input impedence than a bipolar transistor, so the MOSFET can often achieve high power gain with a relatively simple gate driving circuit. In addition, since the MOSFET is a unipolar device, time delay that may be caused by storage or recombination of minority carriers when the device is turned off can be reduced.

Thus, MOSFETs have been widely used in many applications, including switching mode power suppliers, lamp stabilization, motor driving circuits, and the like. MOSFETs can sometimes utilize a diffused MOSFET (DMOSFET) structure using planar diffusion technology. Laterally diffused metal oxide semiconductor (LDMOS) transistors have been recently developed but still exhibit many setbacks.

### BRIEF SUMMARY

Embodiments of the present invention provide highly integrated semiconductor devices and manufacturing methods thereof.

In an embodiment, a semiconductor device can comprise: a buried conductive layer on a semiconductor substrate; an epitaxial layer on the semiconductor substrate including the buried conductive layer; a plug in the epitaxial layer and electrically connected to the buried conductive layer; and an insulating layer. The plug can be substantially laterally surrounded by the insulating layer, such that a top surface and a bottom surface of the plug are not covered by the insulating layer but at least a majority of the sides of the plug is surrounded by the insulating layer.

In another embodiment, a method of fabricating a semiconductor device can comprise: forming a buried conductive layer on a semiconductor substrate; forming an epitaxial layer on the semiconductor substrate including the buried conductive layer; forming a trench in the epitaxial layer; forming an insulating layer on a sidewall of the trench; and forming a plug in the trench and electrically connected to the buried conductive layer. The plug can be substantially laterally surrounded by the insulating layer.

In certain embodiments, the plug can be completely laterally surrounded by the insulating layer, such that the entire side of the plug is surrounded by the insulating layer, though the top surface and the bottom surface of the plug are not covered by the insulating layer.

According to embodiments of the present invention, an insulating layer can surround the plug, helping to inhibit a punch through phenomenon even if an interval between the plug and another conductive region is narrow. For example, an interval between the plug and a source region and/or a drain region can be narrow, and the insulating layer can help inhibit a punch through phenomenon. Thus, semiconductor devices according to embodiments can be highly integrated and manufactured with a reduced width.

### BRIEF DESCRIPTION OF THE DRAWINGS

FIG. 1 is a cross-sectional view showing an LDMOS transistor according to an embodiment of the present invention.

FIGS. 2a to 2d are cross-sectional views showing a method of fabricating an LDMOS transistor according to an embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

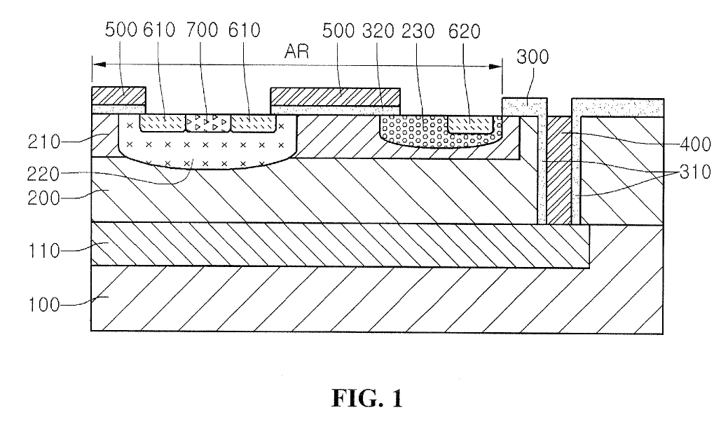

FIG. 1 is a cross-sectional view showing a laterally diffused metal oxide semiconductor (LDMOS) transistor according to an embodiment of the present invention.

Referring to FIG. 1, the LDMOS transistor can include a buried conductive layer 110 disposed on at least a portion of a semiconductor substrate 100. An epitaxial layer 200 can be disposed on the buried conductive layer 110 and the semiconductor substrate 100. A p-body layer 210 can be disposed on at least a portion of the epitaxial layer 200, and an isolation layer 300 can have a portion disposed on a portion of a top surface of the p-body layer 210 and the epitaxial layer 200.

A p-well 220 can be disposed in the p-body layer 210, and a source region 610 can be disposed in the p-well 220. In an embodiment, a portion of the p-well 220 can extend into the epitaxial layer 200.

An n-well 230 can be disposed in the p-body layer 210, and a drain region 620 can be disposed in the n-well 230.

A gate insulating layer 320 can be disposed on the substrate 100 on a region between the p-body layer 210 and the n-well 230, and a gate electrode 500 can be disposed on the gate insulating layer 320.

A plug 400 and an insulating layer 310 can be provided in the epitaxial layer 200. In an embodiment, the plug 400 can be electrically connected to the buried conductive layer 110.

The semiconductor substrate 100 can be any suitable substrate known in the art. For example, the semiconductor substrate 100 can comprise silicon and p-type impurities.

The buried conductive layer 110 can be disposed in the semiconductor substrate 100. In an embodiment, the buried conductive layer 110 can be heavily doped with n-type impurities.

The epitaxial layer 200 can be disposed on the buried conductive layer 110. In an embodiment, the epitaxial layer 200 can be doped with p-type impurities.

The isolation layer 300 can be disposed on the epitaxial layer 200 and serve to isolate the semiconductor device.

The p-body layer 210 can be disposed on the epitaxial layer 200. In an embodiment, the p-body layer 210 can be doped with p-type impurities at a concentration higher than that of the epitaxial layer 200.

The p-well 220 can be disposed in the p-body layer 210 and can include p-type impurities. In an embodiment, the p-well 220 can be doped with p-type impurities at a higher concentration than that of the p-body layer 210. In a particular embodiment, the p-well 220 can pass through the p-body layer 210 and be disposed in part in the epitaxial layer 200.

The n-well 230 can be disposed in the p-body layer 210 and can include n-type impurities. In an embodiment, the n-well 230 can be disposed spaced apart from the p-well 220, such that the n-well 230 is not in contact with the p-well 220.

The source region 610 can be disposed in the p-well 220. The source region 610 can be heavily doped with n-type impurities.

In an embodiment, two source regions 610 can be provided in the p-well 220, and an isolation region 700 can be disposed between them to isolate them from each other. The isolation region 700 can include impurities at a concentration higher than that of the p- type impurities of the p-well 220.

The drain region 620 can be disposed in the n-well 230 and can be heavily doped with n-type impurities.

The gate electrode 500 can be disposed between the source region 610 and the drain region 620. The gate electrode 500 can be formed of any suitable material known in the art, for example, metal or poly-silicon.

The gate insulating layer 320 can be provided under the gate electrode 500 and on the p-body layer 210. The gate insulating layer 320 can help insulate the gate electrode 500 from the p-body layer 210.

In an embodiment, the plug 400 can pass through the epitaxial layer 200 and make contact with the buried conductive layer 110. The plug 400 can be formed of any suitable material known in the art. For example, the plug 400 can include poly-silicon, and the poly-silicon can be doped with n-type impurities. Additionally, or alternatively, the plug 400 can include metal.

In certain embodiments, the plug 400 can be electrically connected to ground through a metal interconnection (not shown). In an embodiment, the plug 400 can have a column shape.

The insulating layer 310 can be provided around the plug 400. That is, the plug 400 can be substantially laterally surrounded by the insulating layer 310, such that a top surface and a bottom surface of the plug 400 are not covered by the insulating layer 310 but at least a majority of the sides of the plug 400 is surrounded by the insulating layer 310. In an embodiment, approximately the entire side of the plug 400 is surrounded by the insulating layer 310, though the top surface and the bottom surface of the plug 400 are not covered by the insulating layer 310. In a further embodiment, the plug 400 is completely laterally surrounded by the insulating layer 310, such that the entire side of the plug 400 is surrounded by the insulating layer 310, though the top surface and the bottom surface of the plug 400 are not covered by the insulating layer 310.

In embodiments where the plug 400 has a column shape, the insulating layer 310 can insulate the plug 400 from the epitaxial layer 200. The insulating layer 310 can be formed of any suitable insulating material known in the art, for example, an oxide layer such as silicon dioxide.

In embodiments of the present invention, since the plug 400 can be surrounded by the insulating layer 310, a punch through phenomenon between the plug 400 and the drain region 620 can be inhibited, even if the space between the plug 400 and the drain region 620 is narrow.

Thus, according to embodiments, a narrow interval can be formed between the plug 400 and the drain region 620, and the horizontal width of the LDMOS transistor can be reduced.

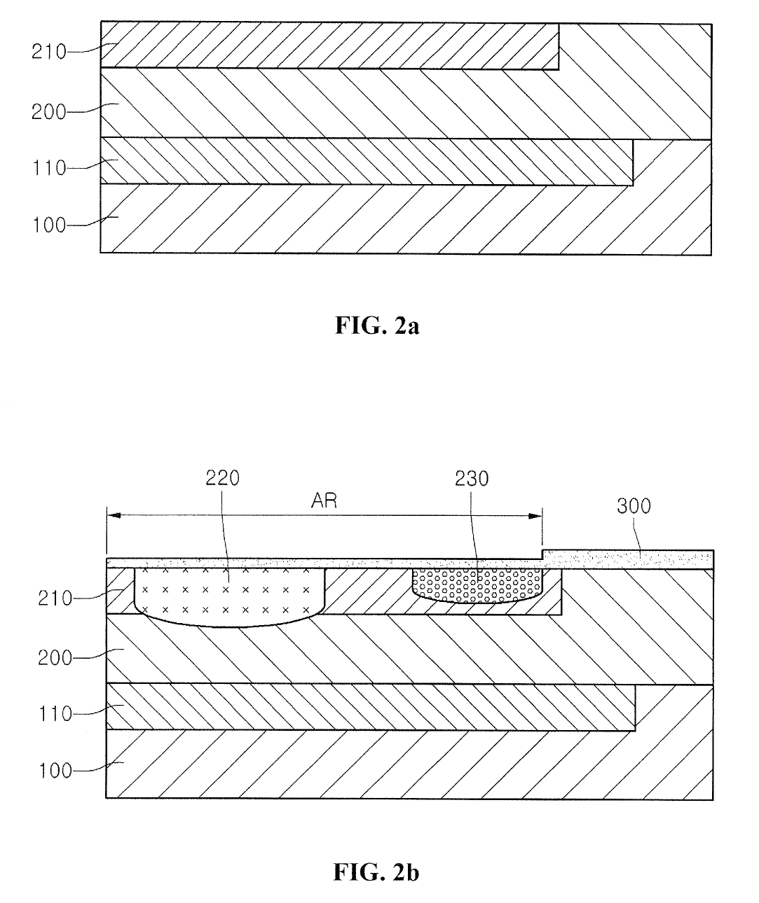

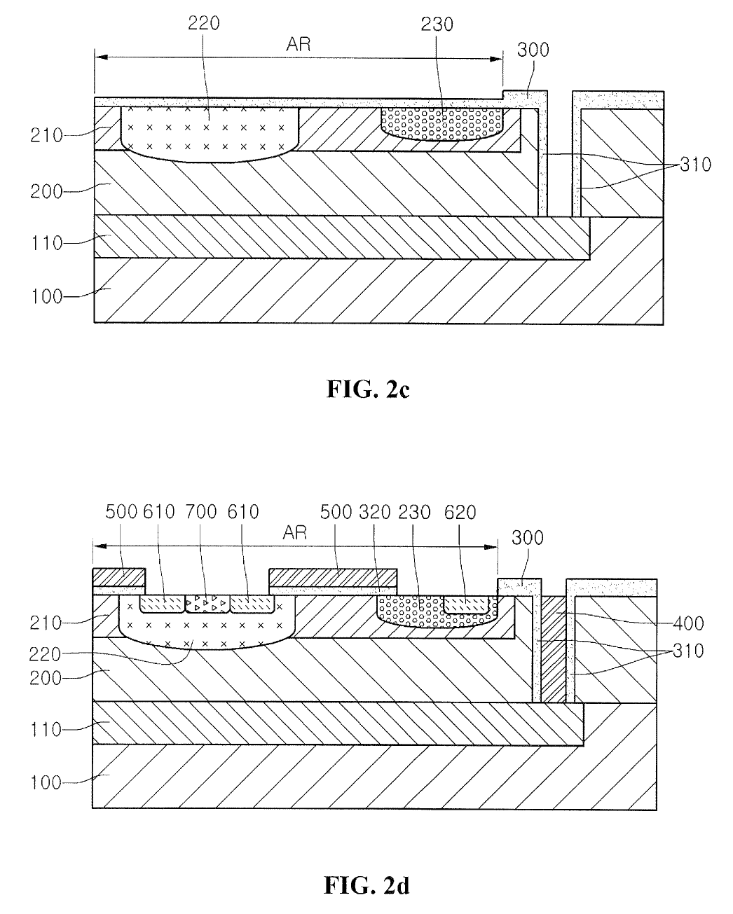

FIGS. 2a to 2d are cross-sectional views showing a method of fabricating an LDMOS transistor according to an embodiment of the present invention.

Referring to FIG. 2a, the buried conductive layer 110 can be formed on the semiconductor substrate 100. The semiconductor substrate 100 can be, for example, a p-type substrate. In an embodiment, the buried conductive layer 110 can be formed by implanting n-type impurities at a high concentration into the semiconductor substrate 100.

After forming the buried conductive layer 110, the epitaxial layer 200 can be formed on the semiconductor substrate 100 and the buried conductive layer 110. The epitaxial layer 200 can be formed through any suitable process known in the art, for example, a vapor phase epitaxy (VPE) process or a liquid phase epitaxy (LPE) process, including p-type impurities.

After forming the epitaxial layer 200, p-type impurities can be implanted into a predetermined region of the epitaxial layer 200 to form the p-body layer 210.

Referring to FIG. 2b, after forming the p-body layer 210, p-type impurities can be implanted into a predetermined region of the p-body layer 210 to form the p-well 220. In an embodiment, the p-well 220 can be formed by implanting p-type impurities at a concentration higher than that of the p-body layer 210.

In a particular embodiment, the p-well 220 can pass through the p-body layer 210 and into the epitaxial layer 200.

After forming the p-well 220, n-type impurities can be implanted into a predetermined region of the p-body layer 210 to form the n-well 230. The n-well 230 can be spaced apart from the p-well 220, such that the n-well 230 and the p-well 220 are not in contact with each other.

After forming the n-well 230, a first oxide layer covering the epitaxial layer 200, the p-body layer 210, the p-well 220 and the n-well 230 can be formed. The first oxide layer can define an active region AR and can be partially etched. An unetched portion of the oxide layer can form the isolation layer 300.

Referring to FIG. 2c, after etching the oxide layer, a trench can be formed through the isolation layer 300 and the epitaxial layer 200. The trench can pass through the isolation layer 300 and the epitaxial layer 200 to expose a portion of the buried conducive layer 110. In an embodiment, the trench can be formed using a mask and etching process.

After forming the trench, a second oxide layer can be formed and can cover the first etched oxide layer of the active region AR, the isolation layer 300, the inner surface of the trench, and the exposed portion of the buried conductive layer 110. The second oxide layer can be formed through any suitable process known in the art, for example, a thermal oxidation process or a chemical vapor deposition (CVD) process.

Then, a portion of the second oxide layer covering the buried conductive layer 110 can be removed, thereby forming the insulating layer 310 in the trench. The portion of the second oxide layer can be removed, for example, through an isotropic etch process.

Referring to FIG. 2d, after forming the insulating layer 310, the plug 400 can be formed in the trench having the insulating layer 310 on the sidewall surfaces thereof.

In one embodiment, in order to form the plug 400, n-type impurities and poly-silicon can be deposited in the trench and on the semiconductor substrate 100. Then, the poly-silicon, except for at least a portion of the doped poly-silicon in the trench, can be removed through an etchback process, thereby forming the plug 400.

In an alternative embodiment, poly-silicon can be deposited in the trench and on the semiconductor substrate 100. Then, the polysilicon, except for at least a portion of the polysilicon in the trench, can be removed through an etchback process. Next, n-type impurities can be implanted at a high concentration into the trench, thereby forming the plug 400.

After forming the plug 400, a third oxide layer (not shown) can be formed on the semiconductor substrate 100. Then, a gate electrode layer (not shown) can be formed on the third oxide layer. The gate electrode layer can be any suitable material known in the art, for example, poly-silicon or metal. The third oxide layer and the gate electrode layer can be patterned to form the gate insulating layer 320 and the gate electrode 500, respectively. At this time, the gate electrode 500 can be formed between the p-well 220 and the n-well 230.

After forming the gate electrode 500, n-type impurities can be implanted at a high concentration into predetermined regions of the p-well 220 and the n-well 230, thereby forming the source region 610 and the drain region 620 in the p-well 220 and the n-well 230, respectively.

In an embodiment, two source regions 610 can be formed in the p-well 220 for adjacent devices and can be spaced apart from each other by an isolation region 700. The isolation region can be formed by, for example, implanting p-type impurities at a high concentration between the source regions 610.

In certain embodiments, metal interconnections (not shown) can be formed to electrically connect with the source region 610, the drain region 620, and/or the plug 400.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a buried conductive layer in a semiconductor substrate;
an epitaxial layer on the buried conductive layer; and
a plug in the epitaxial layer and electrically connected to the buried conductive layer;
wherein the plug is substantially laterally surrounded by an insulating layer.

2. The semiconductor device according to claim 1, further comprising:
a conductive body layer in the epitaxial layer;
a first conductive well in the conductive body layer;
a second conductive well in the conductive body layer and spaced apart from the first conductive well;
at least one source region in the first conductive well; and
a drain region in the second conductive well.

3. The semiconductor device according to claim 2, wherein the conductive body layer comprises p-type impurities; wherein the first conductive well comprises p-type impurities; and wherein the second conductive well comprises n-type impurities.

4. The semiconductor device according to claim 3, wherein a concentration of p-type impurities of the first conductive well is higher than a concentration of p-type impurities of the conductive body layer.

5. The semiconductor device according to claim 3, wherein the at least one source region comprises n-type impurities, and wherein the drain region comprises n-type impurities.

6. The semiconductor device according to claim 2, further comprising a gate electrode and a gate insulating layer on the conductive body layer between the first conductive well and the second conductive well.

7. The semiconductor device according to claim 1, wherein the plug is electrically connected to a ground.

8. The semiconductor device according to claim 1, wherein the plug is in physical contact with at least a portion of the buried conductive layer.

9. The semiconductor device according to claim 1, wherein the buried conductive layer comprises n-type impurities.

10. The semiconductor device according to claim 1, wherein the plug comprises poly-silicon and n-type impurities.

11. A method of fabricating a semiconductor device, comprising:
forming a buried conductive layer in a semiconductor substrate;
forming an epitaxial layer on the semiconductor substrate including the buried conductive layer;
forming a trench in the epitaxial layer;
forming an insulating layer on a sidewall of the trench; and
forming a plug in the trench electrically connected to the buried conductive layer;
wherein the plug is substantially laterally surrounded by the insulating layer.

12. The method according to claim 11, further comprising:
forming a conductive body layer in the epitaxial layer;
forming a first conductive well in the conductive body layer;
forming a second conductive well in the conductive body layer and spaced apart from the first conductive well;
forming at least one source region in first conductive well; and
forming a drain region in the second conductive well.

13. The method according to claim 12, wherein forming the buried conductive layer comprises implanting n-type impurities in the semiconductor substrate; wherein forming the conductive body layer comprises implanting p-type impurities in the epitaxial layer; wherein forming the first conductive well comprises implanting p-type impurities in the conductive body layer; and wherein forming the second conductive well comprises implanting n-type impurities in the conductive body layer.

14. The method according to claim 13, wherein forming the at least one source region comprises implanting n-type impurities in the first conductive well; and wherein forming the drain region comprises implanting n-type impurities in the second conductive well.

15. The method according to claim 14, wherein two source regions are formed in the first conductive well, the method further comprising implanting p-type impurities at high concentration between the two source regions.

16. The method according to claim 12, further comprising forming a gate insulating layer and a gate electrode on the conductive body layer between the first conductive well and the second conductive well.

17. The method according to claim 11, wherein the plug is formed to electrically connect to a ground.

18. The method according to claim 11, wherein forming the trench in the epitaxial layer comprises forming the trench through the epitaxial layer and exposing at least a portion of the buried conductive layer; and wherein forming the plug comprises forming the plug in physical contact with the exposed portion of the buried conductive layer.

19. The method according to claim 11, wherein the plug comprises poly-silicon and n-type impurities.

20. The method according to claim 11, further comprising:
depositing an initial insulating layer on the semiconductor substrate including the epitaxial layer;
etching a portion of the initial insulating layer corresponding to an active area to reduce the thickness of the portion of the initial insulating layer;
wherein forming the trench in the epitaxial layer comprises etching through the initial insulating layer and the epitaxial layer at a region adjacent to the active area; and
wherein forming the insulating layer on the sidewall of the trench comprises:
depositing the insulating layer on the initial insulating layer and in the trench; and
performing an isotropic etching process to remove the insulating layer from the bottom of the trench.
